(19) United States
(12) Patent Application Publication
(10) Pub. No.: US 2008/0211698 A1
(43) Pub. Date: Sep. 4, 2008

(54) Keyboard with Variable Markings and Layouts

(76) Inventor: Adina Zach, Tel Aviv (IL)

Correspondence Address: Pearl Cohen Zedek Latzer, LLP, 1500 Broadway, 12th Floor, New York, NY, 10036, US

(21) Appl. No.: 11/579,398

(22) PCT Filed: May 1, 2005
(86) PCT No.: PCT/IL2005/000453

§ 371 Date: Nov. 8, 2007

Related U.S. Application Data
(60) Provisional application No. 60/566,944, filed on May 3, 2004.

(51) Int. Cl. H03K 17/94

(52) U.S. Cl. 341/23

(57) ABSTRACT

Currently, there are several types of information input devices into a computer, PDA, cell phone or any appliance requiring data input. One of the most commonly used is the keyboard. The current keyboards (except the virtual keyboards) are limited in the number of language/sign characters marked on the keys as these marking are permanent. This invention is about a keyboard where the keys are changeable images that can be easily and quickly changed/re-configured to any set of language or signs groups. This keyboard is not a virtual keyboard but real hardware combined with specific software.

### BACKGROUND OF THE INVENTION

The present invention relates to a data input device which is a keyboard which possesses a great flexibility in use by having a fast and easy way of changing the layout and the very nature of the characters/signs on it. Such keyboard may be used to input data to a variety of devices such as computers, PDAs, controllers cell phones etc.

There are several types of information inputs for electronic devices such as for example computers, PDAs, cell phones or appliances that require data input. One of the most commonly used data input devices is the keyboard.

Current keyboards generally have fixed markings on their keys and are generally limited in the number of language or signs of characters that may be marked on the keys. Additionally, each key has a few sub characters that can be activated by means of certain master keys (such as Control, Alt, Function etc) but again, these are preset and cannot be changed by the user.

While there are software solutions for substituting these permanent characters on the keyboard by other characters on the computer screen, many of these software solutions are not convenient and require some degree of training.

There are “virtual keyboards” where the keyboard image is projected by a projecting device using for example infra-red or other invisible light on a desk or other flat surface. These keyboards can provide multi-language/signs keys.

One of the virtual keyboards disadvantages is that they may not provide a touch feeling on the keys. Additionally, these keyboards may be expensive.

Other types of virtual keyboards may be those that are displayed on a computer screen with variable layouts. Such virtual keyboards may include for example, those used in restaurants to display for example layouts of the tables or menus, those used in design tools for selecting design-specific uses or layouts, and those used with characters sets that may for example be used for communicating on the Internet.

A drawback to all of these uses may be their predefined forms, lack of flexibility to change the set and layouts, and the fact of being on a computer's main screen may be inconvenient for routing operation of the computer, especially in situations that demand fast and continuous typing.

### SUMMARY OF THE INVENTION

The present invention was done to overcome the shortcomings of the current data input devices as described above and provide easy and flexible mode of data input into computers, PDAs, controllers phones etc.

In order to achieve the above-mentioned objectives, a keyboard made of a touch-sensitive screen, which is made of either a CRT or an LCD. The LCD may be either rigid or flexible (foldable) construction.

On this keyboard, the location of the keys will be either pre-drawn (as rectangles, squares etc) or not at all (in that case the entire description of the key—shape and content) will be created by the computer/chip controlling the keyboard.

The keyboard contains a processor chip that will control the creation of the images on the keyboard screen (these images are the letters, characters, numbers, signs etc. as needed).

This processor will include an operating program and specific programs that will allow for any required language, numbers and signs groups to be created on the keyboard screen at will, as well as translating the position of the key that is touched into signals sent to the computer, PDA, cell phone etc. into the correct protocol to be further processed by these appliances.

A connector between the keyboard and the computer, PDA, cell phone etc. allowing standard interface with them through USB, parallel or any other requested connector type.

The programs controlling the keyboard operation in different languages, signs etc may also be loaded into the computer, PDA etc. standard processors such as any other program, and control from there the keyboard through it's specific processor (included in the keyboard).

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a flow chart showing states of operation of a keyboard in accordance with an embodiment of the invention;

FIG. 2 is a flow chart describing the static layout of the flow of information between the keyboard and the computer/PDA etc. in accordance with an embodiment of the invention;

FIG. 3 is a flow chart describing the dynamic flow of information, instructions and processing of instructions in accordance with an embodiment of the invention; and

FIG. 4 is a framework schematic description of the connections among the major components of the keyboard in accordance with an embodiment of the invention.

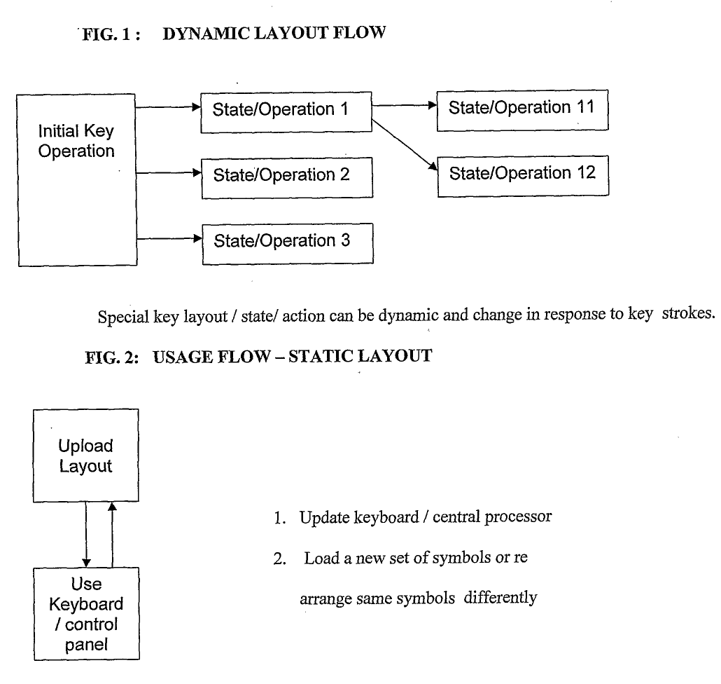

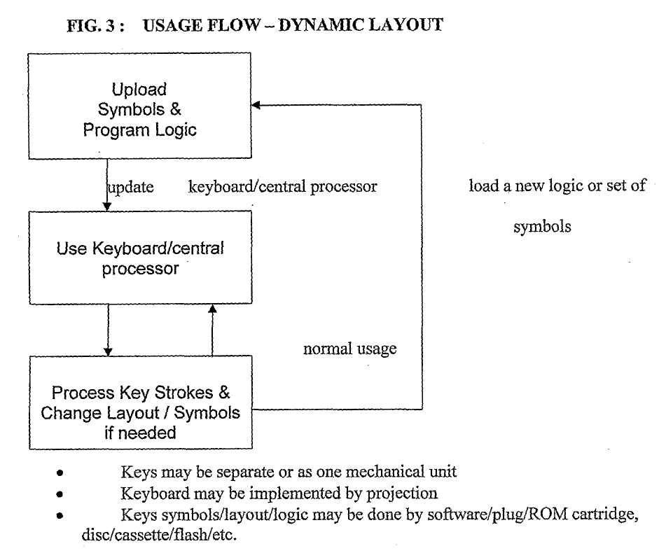

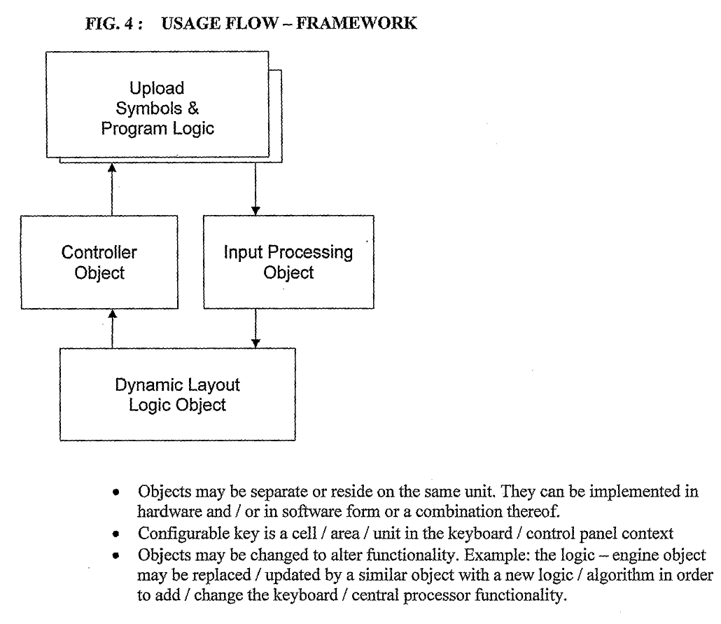

### DETAILED DESCRIPTION OF THE INVENTION

In the following description, various aspects of the invention will be described. For purposes of explanation, specific configurations and details are set forth in order to provide a thorough understanding of the invention. However, it will also be apparent to one skilled in the art that the invention may be practiced without the specific details presented herein. Furthermore, well-known features may be omitted or simplified in order not to obscure the invention. Embodiments of the invention may include the following:

Changeable images or markings, so that such markings may be easily and quickly changed to various sets of language or sign sets.

These language/sign sets are not necessarily pre-fixed. Their layouts may be changed by the user at will and during the typing operation (or “on-the-fly”).

The keys may be displayed on a screen such as for example a touch-sensitive screen that may include a CRT or an LCD.

The keyboard may be manufactured from a flexible LCD sheet that can be completely foldable into a small compact roll so that it is easy to carry.

The keyboard may be manufactured to any suitable size or shape. Other screens or touch sensitive surfaces may be used.

Due to the flexibility of the characters layout and “on-the-fly” operation capability, a small keyboard with normal size keys can be manufactured for special purposes (where small size is dictated due to operational restrictions). This is in contrast to currently available small, uncomfortable to operate, keyboard with miniature keys (due to the necessity to have the complete QWERTY characters layout).

The touch sensitive surface may be rigid, flexible, foldable or may take on other configurations.

The location of keys on the keyboard may in some embodiments be pre-drawn onto the screen and displayed in any desirable shapes such as for example rectangles, squares etc., or alternately may be displayed onto a completely blank screen electronically as part of for example the function of the LCD that displays images.

In such later case, the shape, content and location of keys may be created by the processor chip controlling the keyboard and displayed on the screen and may in some embodiments be dictated by a user.

A processor chip may control the formation or display of images such as letters, characters, numbers, signs etc on the keyboard screen.

The processor may include an operating program and specific programs that may allow for various languages, numbers and signs to be created on the keyboard screen.

In some embodiments, a user may designate his own layout protocols or download into the keyboard a set of protocols containing the signs, symbols or characters that may be displayed on the keyboard screen, and may dictate their placement on the screen.

The number of different characters/signs/symbols layouts and combinations, in this newly invented keyboard, is unlimited and determined only by the number of such programs stored in the processor chip/memory chips. This is in contrast with the currently available keyboards that are severely limited in number and layouts of characters/symbols/signs and their specific locations on the keyboard.

This designation may translate the position of a designated key that is touched on the keyboard screen into signals that may be sent to an electronic device into the correct protocol to be further processed by the device.

The processor may also include a program that will allow the user to define his own invented characters, signs, symbols and their desired layout on the keyboard desired.

The keyboard includes a connection interface to the PC, PDA, Cell phones, controlled machines/devices, TV, kitchen appliance, alarms, washing machines, home service robots, remote control device or other electronic device.

The connection/interface between the keyboard and the electronic device may be based on a USB, parallel or other suitable type of wired connection or wireless connection such as Bluetooth, WAN etc that may be capable of transmitting data at an acceptable rate and using acceptable connection protocols.

The programs controlling the keyboard operation in different languages, signs etc may also be loaded into the computer, PDA or other electronic device in a manner similar to the way other programs may be loaded into such devices i.e. via CDs, cassettes, memory sticks, direct down load from the Internet sites etc.

Upon touching the keyboard at a location where a certain key image is displayed, a protocol or other value representing the character may be transmitted to an electronic device to which the keyboard may be connected. This process may in some embodiments be similar to the way that a standard keyboard operates in feeding symbols or values to a computer or other electronic device.

Changing the language characters or signs sets of a specific keyboard layout may be performed by pressing a certain key or combination of keys (such as “English” for instance for changing into the English characters set). This may permit re-defining or reshaping the characters set or even the entire character layout on the keyboard from the keyboard and “on-the-fly” or during the typing operation on the keyboard.

The display of the keyboard does not have to be pre-divided into squares, rectangles or predefined spaces and the number of languages; sign groups or specific keyboard layouts may be unlimited. This operation of defining which characters set or layout is on the key board at any given moment, may be controlled by for example software in either the keyboard processor or in the electronic device to which the keyboard may be attached, or both, and may be dictated by a user in the course of typing or using the keyboard.

Specific programs that may include other languages, sign groups or specific keyboard layouts may be added via suitable data transfer techniques such as CDs, Internet downloads from a specific web site etc.

The great flexibility of this key board as described above combined with specific programs in the controlling processor, whether in the key board, the electronic device or both, may enable a user to define in the course of use, and use his own characters or signs such as a privately invented language or special encryptions or code, or use, specific signs for special design projects in fields such as architecture, mechanics or others.

Similarly, in some embodiments, a user may configure his own specific layout on the keyboard for specific purposes such as for example—controlling a specific machine for special operating purposes.

Such designs or specific layouts may be saved in the chip or device memory and called back for use from the memory at a single or few keystrokes.

In some embodiments, the keyboard may have its own processor, which may store operating programs such that no customizing configuration may be required of the electronic device to which the keyboard may be attached.

In some embodiments, the keyboard may be equipped with a specific operating program and a number of specific language/sign-packs programs. Additional language/signs—packs maybe acquired/downloaded.

In some embodiments, the keyboard may be used for industrial control panels or keyboards where a mode/layout change may be called for to the control panel to change functions and/or mode of operation for a certain type of equipment or application. The layout of the keyboard may then, be modified for alternating applications of that equipment

While certain features of the invention have been illustrated and described herein, many modifications, substitutions, changes, and equivalents may occur to those of ordinary skill in the art. It is, therefore, to be understood that the appended claims are intended to cover all such modifications and changes as fall within the true spirit of the invention.

I claim:

1. A keyboard or other data input device to a computer, PDA, cell phone or any appliance requiring data input, that includes keys that may be displayed with changeable images or markings, so that such markings may be easily and quickly changed to various sets of language or sign sets.

2. A keyboard or other data input device as per claim 1 that includes a connection interface to the PC, PDA, Cell phones, controlled machines/devices, TV, kitchen appliance, alarms, washing machines, home service robots, remote control device or other electronic device.

3. A keyboard or other data input device as per claim 1 with a connection/interface between the keyboard and the electronic device may be based on a USB, parallel or other suitable type of wired connection or wireless connection such as Bluetooth, WAN etc that may be capable of transmitting data at an acceptable rate and using acceptable connection protocols.

4. A keyboard or other data input device as per claim 1, having keys that may be displayed on a screen such as for example a touch-sensitive screen that may include a CRT or an LCD or a flexible LCD or a flexible paper with conductive ink that can be completely foldable into a small compact roll so that it is easy to carry.

5. A keyboard or other data input device as per claim 1 having the location of keys on the keyboard, in some embodiments, be pre-drawn onto the screen and displayed in any desirable shapes such as for example rectangles, squares etc.

6. A keyboard or other data input device as per claim 1 having the location of keys on the keyboard is displayed onto a completely blank screen electronically as part of for example the function of the LCD that displays images. The shape, content and location of keys may be created by the processor chip controlling the keyboard and displayed on the screen and may in some embodiments be dictated by a user.

7. A keyboard or other data input device as per claim 1 having a processor chip that controls the formation or display of images such as letters, characters, numbers, signs etc on the keyboard screen. The processor may include an operating program and specific programs that may allow for various languages, numbers and signs to be created on the keyboard screen.

8. A keyboard or other data input device as per claim 1 enabling the user to designate his own layout protocols or down-load into the keyboard a set of protocols containing the signs, symbols or characters that may be displayed on the keyboard screen, and may dictate their placement on the screen.

9. A keyboard or other data input device as per claim 1 that includes a specific operating program and a number of specific language/sign-packs programs. Additional language/signs—packs maybe acquired/downloaded.

10. A keyboard or other data input device as per claim 1 having programs controlling the keyboard operation in different languages, signs etc may also be loaded into the computer, PDA or other electronic device in a manner similar to the way other programs may be loaded into such devices i.e. via CDs, cassettes, memory sticks, direct down load from the Internet sites etc.

11. A keyboard or other data input device as per claim 1 having the capability of changing the language characters or signs sets of a specific keyboard layout may be performed by pressing a certain key or combination of keys. This may permit re-defining or re-shaping the characters set or even the entire character layout on the keyboard from the keyboard and “on-the-fly” or during the typing operation on the keyboard.

12. A keyboard or other data input device where the keyboard may be used for industrial control panels or keyboards where a mode/layout change may be called for to the control panel to change functions and/or mode of operation for a certain type of equipment or application. The layout of the keyboard may then, be modified for alternating applications of that equipment
